(19) United States
(12) Patent Application Publication
(10) Pub. No.: US 2007/0184653 A1
(43) Pub. Date: Aug. 9, 2007

(54) Integrated circuit with a very small-sized reading diode

(76) Inventor: Pierre Blanchard, Echirolles (FR)

Correspondence Address: LOWE HAUPTMAN & BERNER, LLP, 1700 DIAGONAL ROAD, SUITE 300, ALEXANDRIA, VA, 22314, US

(21) Appl. No.: 10/591,178

(22) PCT Filed: Feb. 21, 2005
(86) PCT No.: PCT/EP05/50740

§ 371 Date: Aug. 30, 2006

(30) Foreign Application Priority Data
Mar. 2, 2004 (FR) 0402148

(51) Int. Cl. H01L 21/44

(52) U.S. Cl. 438/657

(57) ABSTRACT

The invention relates to integrated circuits comprising both conductive gates deposited above a semiconductor substrate and a diode is formed between two electrodes. In order to achieve a diode of very small dimensions, the following procedure is adopted: producing the electrodes (ELn, GRST, then thermally oxidizing the electrodes, then exposing the surface of the substrate between the electrodes, then the following operations: depositing doped polycrystalline silicon in order to form one pole (42) of the diode, the substrate forming the other pole, delimiting a desired silicon pattern covering the space left between the electrodes and also covering a region lying outside this space, depositing an insulating layer, locally etching an opening into this insulating layer above the polycrystalline silicon outside the space lying between the electrodes, in order to form an offset contact zone, depositing a metal layer and etching the metal layer.

### FIELD OF THE INVENTION

The invention relates to integrated circuits comprising both conductive gates deposited above a semiconductor substrate and diodes formed in this substrate.

### BACKGROUND OF THE INVENTION

The main application envisaged is a readout register for electrical charges, operating by charge transfer in the semiconductor substrate under the influence of variable potentials applied to gates juxtaposed above the substrate and insulated from the substrate. Such registers are present in matrix image sensors produced in CCD (charge coupled device) technology. They are used in particular to recover row-by-row the charges stored in a matrix of photosensitive elements in order to send them to a readout circuit, which converts them into electrical voltages or currents representing the level of charges photogenerated at each point of the row.

The readout register consisting of juxtaposed gates or electrodes generally ends in a diode formed on the substrate, which diode makes it possible to convert a quantity of charges into an electrical voltage level. The readout diode must be as small as possible in order to minimize its capacitance; this is because if the capacitance of the diode is too great, it will prevent operation of the register at very high speeds.

This is why the configuration of the readout register is generally as represented in FIG. 1: the gates or electrodes EL1, EL2 etc. of the register, initially deposited regularly and identically along the register, end in a funnel which concentrates the charges toward a small readout diode DL.

However, the technology used to produce the diode places a lower limit on the size which the diode can be given; this is because the diode is sandwiched between a last electrode ELn of the register and another electrode or silicon gate GRST; the electrode GRST or reset gate constitutes a barrier between the diode and a doped silicon region forming a drain DR, this barrier being used to periodically re-establish the potential of the diode at a constant level before a new readout of charges. On the other hand, the diode should be connected to the rest of the readout circuit (not shown) by at least one electrical connection, and the contact terminal of this connection on the diode occupies non-negligible space making it necessary to use a diode larger than that which is really necessary for operation of the circuit.

### SUMMARY OF THE INVENTION

This is where the present invention provides a method for fabricating a diode of small dimensions between two silicon electrodes deposited above a substrate, which comprises the following steps:
a) producing the two electrodes, separated by a gap, above the substrate,
b) thermally oxidizing a part of the thickness of the electrodes, in height and in width, leaving a space remaining between the oxidized electrodes, the substrate being protected against oxidation in this space;
c) exposing the surface of the substrate in this space,
d) depositing a layer of doped polycrystalline silicon entering in contact with the substrate in this space in order to form one pole of the diode, the substrate forming the other pole,
e) partially removing the polycrystalline silicon while leaving a desired pattern remaining, this pattern covering at least the space left between the electrodes and also covering a region lying outside this space,
f) depositing an insulating layer, locally etching an opening into this insulating layer above the polycrystalline silicon outside the space lying between the electrodes, in order to form an offset contact zone, depositing a metal layer entering in contact with the polycrystalline silicon in the offset contact zone, and etching the metal layer according to a desired pattern of interconnections.

The contact zone is offset with respect to the zone constituting the diode in so far as the conductive layer, preferably a metal and preferably aluminum, enters in contact with the polycrystalline silicon layer at a position which does not lie above the diode.

The following procedure is preferably adopted for step e) of partially removing the polycrystalline silicon: a uniform layer of silicon nitride is deposited on the polycrystalline silicon, this is etched according to a pattern which leaves the layer remaining above the polycrystalline silicon zones that are intended to be kept, and the silicon is subsequently oxidized over its entire thickness wherever it is not covered with nitride, until a silicon pattern is obtained which comprises only the zones that were not covered with nitride. It will be noted that as a variant, the polycrystalline silicon may be chemically attacked between the deposition of the nitride layer and the subsequent step of oxidizing the polycrystalline silicon in order to remove it as much as possible wherever it is not protected by the nitride, before proceeding with the oxidation.

In the case of using silicon nitride, the local opening of the insulating layer in step f) also comprises opening the silicon nitride in order to expose the polycrystalline silicon in the contact zone before depositing the conductive layer.

With this method, it is typically possible to produce a diode with dimensions of about 1.5 micrometer by 1.5 micrometer while a more conventional method, consisting in opening a contact zone in an insulating layer directly above the diode and depositing aluminum above this zone in order to enter in contact with the substrate, would not make it possible to go below 4 micrometers by 4 micrometers in view of the margins which it is necessary to provide when opening the contact zone.

As an application, the invention provides an integrated circuit comprising a CCD register with a readout diode at the end of the register, between the last electrode of the register and a reset electrode, characterized in that the readout diode consists of a doped region delimited on one side by the electrodes and on the other side by regions of thick silicon oxide, the doped region being entirely covered with a layer of polycrystalline silicon delimited according to a pattern which extends partly above the thick oxide, the silicon layer being covered with an insulating layer comprising an opening above the thick oxide but no opening above the doped region, and the insulating layer being itself covered with a conductive layer entering in contact with the polycrystalline silicon through the opening.

### BRIEF DESCRIPTION OF DRAWINGS

Other characteristics and advantages of the invention will become apparent on reading the following detailed description which is given with reference to the appended drawings, in which:

FIG. 1, already described, represents the schematic structure of a CCD readout register;

FIG. 2 represents a plan view and detail of the readout diode which is produced;

FIGS. 3 and 4 represent the readout diode in section, respectively along the line A-A and along the line B-B;

FIGS. 5 to 11 represent the various production steps of the diode; in each figure, the left-hand part represents the substrate cut along the line A-A of FIG. 2, i.e. a line cutting the two electrodes which frame the diode, while the right-hand part represents the substrate cut along the line B-B of FIG. 2, i.e. a line which passes between the electrodes without cutting them.

### DESCRIPTION OF PREFERRED EMBODIMENTS

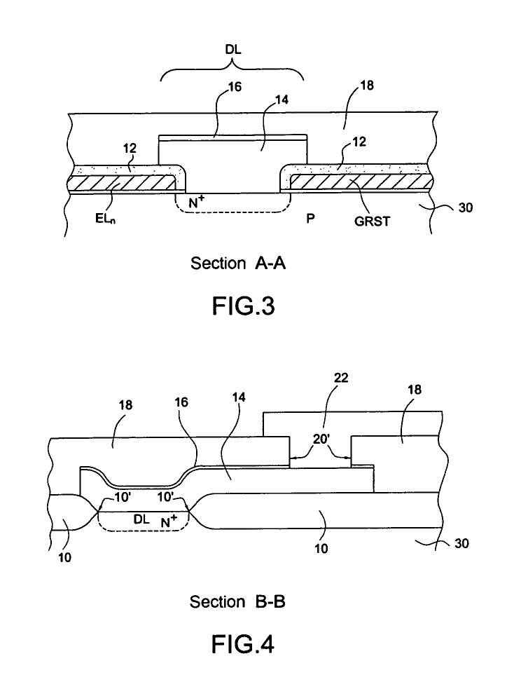

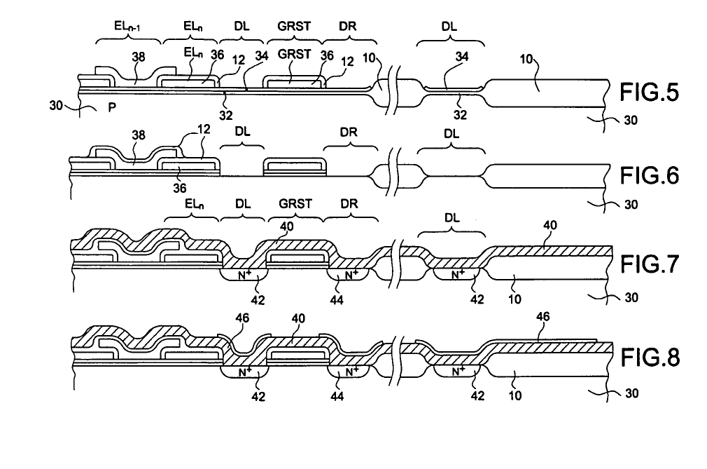

In FIG. 2 (plan view) and FIGS. 3 and 4 (sections along AA and B, respectively), the readout diode DL is defined by an N⁺-type doped zone diffused into the P-type substrate 30. The doped zone constitutes one pole of the diode, and the substrate constitutes another pole.

In the lateral direction of FIGS. 2 and 3 (on the left and on the right in FIG. 2 and in FIG. 3), this zone is delimited in practice by the edges of the two gates or electrodes ELn and GRST which frame it. The electrodes are hatched in FIGS. 2 and 3. In the vertical direction of the page in FIG. 2 (at the top and at the bottom in FIG. 2, on the left and on the right in FIG. 4), the N⁺-type diffused zone is delimited by thick oxide regions 10 (conventional LOCOS thermal oxide). The dashed lines 10′ of FIG. 2 represent the edges of the thick oxide zones 10 framing the diode. The zone corresponding to the diode DL does not comprise thick oxide.

The gates ELn and GRST are made of polycrystalline silicon, and they are covered with an insulating layer of silicon oxide 12 represented by dots in FIGS. 2 and 3.

A layer of conductive polycrystalline silicon 14, N⁺-type doped and etched according to a suitable pattern, enters in contact with all of the substrate zone 30 below the diode DL wherever the substrate is not protected by the gates ELn and GRST and the silicon oxide 10. This silicon layer rises onto the thick oxide 10, as can be seen in FIG. 4. The polycrystalline silicon pattern is delimited by a line 14′ in FIG. 2. This pattern makes it possible to produce an electrical contact between the N⁺ pole of the diode and a conductive layer of aluminum, this contact being offset i.e. not lying above the diode but lying above the thick oxide 10.

The polycrystalline silicon pattern 14 is preferably covered with a layer of silicon nitride 16. The assembly consisting of the polycrystalline silicon pattern 14 and the nitride layer 16 is covered with an insulating passivation layer 18, which also covers other parts of the structure. These two layers 16 and 18 are locally opened at the position of the desired contact with an aluminum layer, i.e. at a position lying above the thick oxide 10 but not above the zone constituting the diode DL. The contact opening thus defined is delimited by the line 20′ in FIG. 2. The metal layer 22 is preferably an aluminum layer, etched according to a desired pattern of interconnections, deposited above the insulating layer 18 and entering in contact with the polycrystalline silicon 14 through the opening formed in the layers of oxide 18 and nitride 16 above the thick oxide 10. It will be noted that the silicon nitride layer is delimited by the same pattern (line 14′) as the polycrystalline silicon layer on which it is deposited, apart from the zones when it is opened in order to allow electrical contact between the polycrystalline silicon layer and the conductive layer 22.

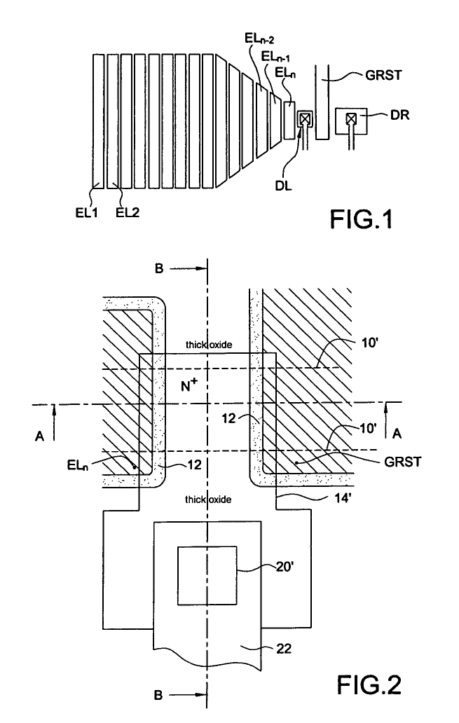

The drain DR conventionally provided (cf. FIG. 1) on the other side of the gate GRST has not been represented in FIGS. 2 to 4. This drain will be made like the readout diode DL, as will be explained below.

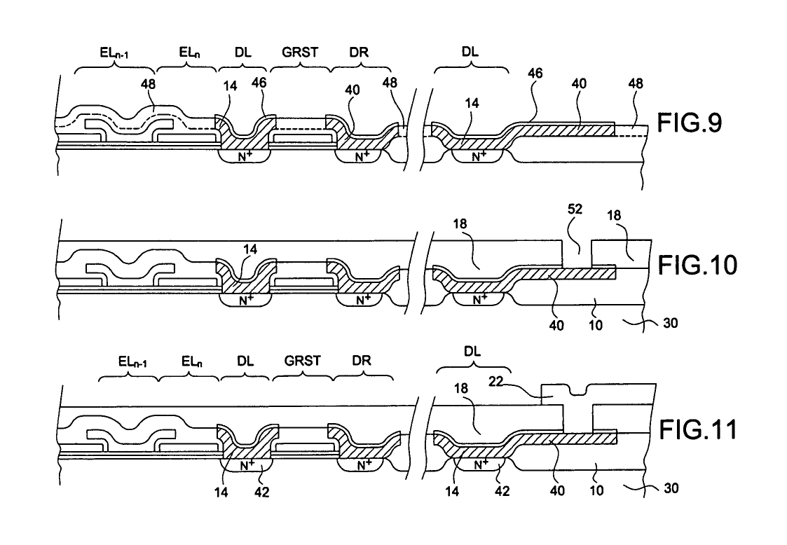

FIG. 5 and the following figures represent the various fabrication steps according to the invention.

They start with a P-type silicon substrate 30 possibly having the doping profile variations necessary for operation (in particular a thin N-type surface layer for bulk transfer, not shown) and polycrystalline silicon gates are formed making it possible to construct electrodes of a CCD register, this being done according to a conventional method which may typically be as follows:
surface oxidation of the substrate, producing a uniform layer of a thin oxide 32;
depositing a uniform thin layer of silicon nitride 34;
etching the nitride according to a pattern corresponding to the desired insulation zones of thick oxide 10;
thick thermal oxidation of the LOCOS type in order to form the zones 10 wherever there is no longer any nitride;
depositing a first uniform layer of polycrystalline silicon 36;
etching this layer 36 in order to define a first series of mutually spaced electrodes of even rank n, n−2, n−4, n−6 etc., which include the electrode ELn as well as the electrode GRST; the electrodes of odd rank n−1, n−3, n−5 will subsequently be interposed between the even ranked electrodes;
thermal oxidation of the layer 36 so that the silicon of this layer is covered laterally and on the surface with insulating silicon oxide 12;
uniformly depositing a second layer of polycrystalline silicon 38 which, in particular, fills the space between the electrodes formed in the first layer (for example between the electrode ELn of rank n and the electrode of rank n−2 which precedes it in the first series);
etching the second layer 38 in order to define a second series of electrodes, of odd rank; the two series of juxtaposed electrodes form a register allowing charge transfer in the substrate by applying variable potentials to the electrodes; the polycrystalline silicon of the second layer 38 is entirely removed in the space between the gates ELn and GRST, i.e. the space reserved for the readout diode DL, as well as in the space which will be reserved for forming a drain DR.

FIG. 5 represents the integrated circuit at this stage of fabrication.

The following steps, which are more specific to the invention, will now be described.

The upper surface of the assembly is surface-oxidized by a thermal oxidation method. The polycrystalline silicon of the second layer 38 is covered on the surface and laterally with an insulating oxide layer, in the same way as the polycrystalline silicon of the layer 36 was covered with an oxide layer 12. During the same oxidation operation, the thickness 12 of the layer increases. Given that the oxide layers formed during these two oxidation operations are of the same nature, the oxide layer which covers all the electrodes at the end of this second operation of oxidizing the polycrystalline silicon has been denoted by a single reference 12 in FIG. 6.

At the end of this oxidation operation, the nitride layer 34 is removed wherever it is not protected by the electrodes, i.e. in the zones DL and DR reserved for the readout diode and the reset drain. The very thin silicon oxide layer 32 which is exposed by removing the nitride is also removed. These last two operations essentially do not affect the layer 12, which is much thicker than the layer 32.

FIG. 6 represents the integrated circuit at the end of this step.

A third uniform layer 40 of polycrystalline silicon is then deposited, which fills in particular the space between the electrodes ELn and GRST as well as the space reserved for the drain DR, and which enters directly in contact with the substrate 30 exposed in these spaces. This layer 40 will subsequently form the polycrystalline silicon interconnection pattern 14 in FIGS. 2 to 4.

The silicon of the layer 40 is doped heavily with an N-type impurity, either during the deposition (deposition in the presence of arsenic) or after the deposition, and a sufficiently intense and prolonged heat treatment is carried out so that the N-type impurities diffuse into the substrate wherever the polycrystalline silicon is in contact with the exposed substrate (regions DL and DR). An N⁺-type diffused region 42 which constitutes a first pole of the readout diode DL is thus formed in the substrate, the substrate constituting a second pole; an N⁺-type diffused region 44, which constitutes the drain DR, is also formed at the same time. It should be noted that the heat treatment may be distributed during the subsequent fabrication steps (particularly during the oxidation operations), although it is assumed to be done at this time to simplify explanation.

FIG. 7 represents the circuit at this stage.

Successive operations intended to delimit polycrystalline silicon zones of the layer 40 are then carried out in order to form desired patterns of interconnection with this layer. As more specifically regards the readout diode, the interconnection pattern is the pattern delimited by the line 14′ in FIG. 2, i.e. a pattern which makes it possible to offset the aluminum contact (which will be established subsequently) elsewhere than above the readout diode. Another pattern may be established in order to connect the drain region DR, as well as yet other patterns on the rest of the integrated circuit.

The polycrystalline silicon could be etched by chemical attack of the layer 40 through a photoetched masking resist, although simple etching of the silicon presents risks of problematic defects; this is because when the relief of the surface is accentuated, the etching can leave abrupt relief transitions of the silicon residues which cause short circuits. It is preferable to proceed in a different way:

a) a layer of silicon nitride 46 is deposited on the uniform layer 40, and this layer is etched according to a pattern which leaves only the desired interconnection zones remaining. FIG. 8 represents the circuit at this stage. It can be seen that a nitride zone 46 has been kept which, on the one hand, covers the region of the readout diode 42 and, on the other hand, extends over the thick oxide 10.

b) a deep oxidizing heat treatment of the polycrystalline silicon of the third layer 40 is then carried out. This oxidation takes place in the bulk of the silicon wherever it is not protected by the nitride 46. The polycrystalline silicon is entirely converted into silicon oxide 48 wherever it is not protected. This leads to the structure in FIG. 9, with a pattern of polycrystalline silicon interconnections 40 covered with nitride and, outside this pattern, a silicon oxide layer 48 protecting all the electrodes of the register.

It will be noted that after depositing and etching the nitride, it would also have been possible to etch the polycrystalline silicon layer 40 by chemical attack through the same mask as that used to etch the nitride layer 46, and then carry out only step b, i.e. thermal oxidation of the residues which could remain after this etching of the silicon.

After having thus defined the interconnection patterns of the layer 40, leading to an interconnection pattern 14 defined in respect of FIGS. 2 to 4, an insulating protective layer 18 which may also be used as a planarizing layer is then deposited (layer of oxide or polyimide in particular). A local opening 50 is made in this layer and in the underlying nitride layer 46, at a position where a contact with the polycrystalline silicon interconnection pattern 40 is desired. The opening 50, which is used to establish the electrical contact with the N⁺ region 42 of the readout diode, lies above the thick oxide 10 as can be seen in FIG. 10; its contour corresponds to the contour 20′ in FIG. 2.

Lastly (FIG. 11) a conductive layer 22 is deposited, preferably an aluminum layer, and this layer is etched according to the desired interconnection patterns. The layer 22 fills the opening 50 and enters in contact with the polycrystalline silicon, thereby indirectly entering in contact with the N⁺ region of the readout diode DL.

The dimension of the diode DL may be merely 1.5 micrometer by 1.5 micrometer, which would not be possible if the aluminum contact came above the diode (the minimal dimension would instead be 4.5 by 4.5 micrometers).

1. A method for fabricating a diode (DL) of small dimensions between two silicon electrodes deposited above a substrate, comprising the following steps:
a) producing the two electrodes, separated by a gap, above the substrate;
b) thermally oxidizing a part of a thickness of the electrodes, in height and in width, leaving a space remaining between the oxidized electrodes, the substrate being protected against oxidation in the space;
c) exposing the surface of the substrate in the space,
d) depositing a layer of doped polycrystalline silicon entering in contact with the substrate in the space in order to form one pole of the diode, the substrate forming another pole,
e) partially removing the polycrystalline silicon while leaving a desired pattern remaining, the pattern covering at least the space left between the electrodes and also covering a region lying outside the space,
f) depositing an insulating layer, and locally etching an opening into the insulating layer above the polycrystalline silicon outside the space lying between the electrodes, in order to form an offset contact zone, depositing a metal layer entering in contact with the polycrystalline silicon in the offset contact zone, and etching the metal layer according to a desired pattern of interconnections.

2. The method as claimed in claim 1, wherein step e) includes: depositing a uniform layer of silicon nitride and etching according to a pattern which leaves the layer remaining above the polycrystalline silicon zones that are intended to be kept, and the silicon is subsequently oxidized over its entire thickness wherever it is not covered with nitride, until a silicon pattern is obtained which comprises only the zones that were not covered with nitride.

3. The method as claimed in claim 2, wherein between the deposition of the nitride layer and the subsequent step of oxidizing the polycrystalline silicon, the polycrystalline silicon is chemically attacked in order to remove it as much as possible wherever it is not protected by the nitride.

4. An integrated circuit comprising
a CCD register with a readout diode at the end of the register, between the last electrode of the register and a reset electrode, wherein the readout diode includes a doped region delimited on one side by the electrodes and on the other side by regions of thick silicon oxide, the doped region being entirely covered with a layer of polycrystalline silicon delimited according to a pattern which extends partly above the thick oxide, the silicon layer being covered with an insulating layer having an opening above the thick oxide but no opening above the doped region, and the insulating layer being itself covered with a conductive layer entering in contact with the polycrystalline silicon through the opening.

5. The integrated circuit as claimed in claim 4, wherein the polycrystalline silicon layer is covered with silicon nitride, itself covered by the insulating layer, the nitride layer also being open at the position of the opening in the insulating layer.
